(19) United States
(12) Patent Application Publication
(10) Pub. No.: US 2012/0222717 A1
(43) Pub. Date: Sep. 6, 2012

(54) METHODS OF ASSEMBLING SOLAR CELLS INTO AN ASSEMBLY, ASSOCIATED APPARATUS, SOLAR PANEL ASSEMBLIES, AND SOLAR CELLS

(75) Inventors: Naga Chandrasekaran, Boise, ID (US); Gurtej S. Sandhu, Boise, ID (US)

(73) Assignee: MICRON TECHNOLOGY, INC., Boise, ID (US)

(21) Appl. No.: 13/038,121

(22) Filed: Mar. 1, 2011

(51) Int. Cl. H01L 31/042; H01L 31/18

(52) U.S. Cl. 136/244; 438/66; 257/E31.001

(57) ABSTRACT

A method of assembling elongate solar cells into an assembly may comprise forming a unitary structure comprising a plurality of elongate solar cell precursor structures from a semiconductor wafer and attaching an adhesive surface of a transfer structure to an edge of each of the plurality of elongate solar cell precursor structures. The method may further comprise attaching the plurality of elongate solar cells to an expandable fixture and expanding the expandable fixture to change at least one of an orientation and a position of the plurality of elongate solar cells relative to one another. Additionally, a solar panel assembly may comprise a plurality of elongate solar cells positioned on a substrate, major surfaces of the plurality of elongate solar cells oriented in a non-planar configuration. Furthermore, elongate solar cells may comprise non-linear shapes in an as-formed state. Transfer structures and expandable fixtures useful in performing methods of the disclosure are also described.

### TECHNICAL FIELD

Embodiments of the present disclosure relate to elongate solar cells and assemblies thereof and, additionally, to methods of assembling elongate solar cells into assemblies and to apparatus useful in performing such methods.

### BACKGROUND

In order to increase the surface area of a bulk semiconductor substrate such as a semiconductor wafer that may for example be utilized for collecting solar energy, a wafer may be processed and cut through a thickness thereof into a large number of thin elongate solar cells, called “slivers.” The elongate solar cells, which have come to be known in the art as “slivers” are generally in a parallelepiped form with a relatively high aspect ratio of length to height and width, or thickness. The elongate solar cells that are cut from the wafer may then be arranged on a substrate with one or both major faces positioned to receive solar radiation, and conductively connected to form an array or sub-array for a solar collecting panel.

Such thin, elongate structures are also known by those of ordinary skill in the art as substrate slivers, elongate substrates, sliver substrates, substrate slivers, plank substrates, slivers, sliver structures, or merely slivers. Further, a thickness of a sliver structure is typically four to one hundred times smaller than a height thereof. The length and height of a sliver structure define the dimensions of opposing major faces of the structure. The thickness or width of a sliver structure is the distance between opposing major faces of the sliver structure. A representative sliver structure may be about 10 mm to about 120 mm long, about 0.5 mm to about 5 mm high, and about 15 microns to about 400 microns thick. Of course, these dimensions may vary depending on the intended application for the sliver structure and the type and dimensions of a bulk semiconductor substrate from which a sliver is severed.

As noted above, one conventional use for slivers is as photovoltaic devices or solar cells assembled with a large number of other slivers to form a solar panel. Each sliver structure may be configured as a small solar cell also known as an elongate solar cell, solar sliver, solar sliver cell, or the like. Elongate solar cells can be produced by processes such as those described in “HighVo (High Voltage) Cell Concept” by S. Scheibenstock, S. Keller, P. Fath, G. Willeke and E. Bucher, Solar Energy Materials & Solar Cells Vol. 65 (2001), pages 179-184 (“Scheibenstock”), and in International Patent Application Publication No. WO 02/45143 (“the Sliver Patent”). The latter document describes processes for producing a large number of thin (generally <150 μm) elongate silicon substrates from a single conventional silicon wafer, where the dimensions of the major faces of resulting thin elongate substrates are such that their total surface area is far greater than a major surface of the original silicon wafer. Such elongate substrates are referred to in the Sliver Patent as “sliver substrates.” The Sliver Patent also describes processes for forming solar cells on sliver substrates, referred to as “sliver solar cells”. The word “sliver” generally refers to a sliver substrate or sliver structure which may or may not incorporate one or more solar cells. The word “SLIVER” is a registered trade mark of Origin Energy Solar Pty Ltd, Australian Registration No. 933476.

In general, elongate solar cells can be single-crystal solar cells or multicrystalline solar cells formed from elongate substrates. The elongate substrates are conventionally formed in a batch process by cutting a series of parallel elongate slots through a thickness of a silicon wafer to define a corresponding series of mutually parallel, thin elongate substrates separated from one another along their adjacent lengths and heights and joined together at their outer ends by the remaining portions of the wafer, referred to as the wafer frame. Solar cells can be formed from the elongate substrates while they remain in the wafer frame, and subsequently separated from each other and from the wafer frame to provide a set of individual elongate solar cells.

The elongate sliver structures from which elongate solar cells are formed are extremely fragile and, thus, require careful handling, in particular during separation from the host wafer, testing, sorting and binning, storage, mounting and electrical interconnection. Additionally, since the area of the major faces and power generation value of each elongate solar cell is extremely small when compared with the surface area of conventional (i.e., non-elongate, wafer- or other bulk semiconductor substrate-based) solar cells, there is a need for reliable, low cost handling, assembly, and mounting processes to form a solar panel from large numbers (e.g., thousands or tens of thousands) of elongate solar cells in order to make use of the elongate solar cells formed from sliver structures economically viable. Existing approaches to using elongate solar cells to form photovoltaic devices have been limited in scope. Some applications have involved gluing the elongate solar cells to a substrate or a transparent or semi-transparent superstrate such as glass, to form a solar panel comprising an array of electrically connected elongate solar cells having major faces oriented upwardly to capture solar radiation. A “pick and place” robotic machine can be used to position the elongate solar cells on the substrate or superstrate.

Conventional solar panel modules, particularly modules constructed using mono-crystalline or multicrystalline silicon wafers, typically contain around 60 to 70 wafer cells per square meter of module area. The wafer cells used in most conventional modules are mono-facial (i.e., they provide only one active surface exposed for illumination), and there is no difficulty identifying the correct orientation of the cells. The large (e.g., typically 4 inch) diameter of conventional wafer cells also means that there is virtually no likelihood of the cells being misoriented in the handling and assembly processes. The number of electrical connections in a module comprising conventional wafers is of the order of 200, or around 3 to 4 per cell.

With elongate solar cells, the number of electrical connections may be around six or eight per cell, but because the area of each elongate cell is only a small fraction of the area of a conventional wafer cell, the number of electrical connections for modules incorporating only elongate solar cells may be in the range of 2,000 to 20,000 or more per square meter of solar panel module area. Thus, a non-conventional approach is required in order to reliably and inexpensively establish inter-cell electrical interconnections of solar panel modules incorporating elongate solar cell sub-module assemblies.

Furthermore, the mono-facial nature of conventional solar cells allows their orientation and polarity to be easily determined visually. However, elongate solar cells can be bifacial (i.e., have two opposing optically active faces), and can also be perfectly symmetrical in physical appearance, making visual determination of their polarity impossible. Elongate solar cells, having a very large aspect ratio, can readily warp or bend if they are thin enough, but at the same time are quite brittle when subjected to localized stress and may fracture or become otherwise damaged during separation, handling, testing, binning, and assembly.

As noted above, the thinness of the elongate solar cells, in conjunction with the high aspect ratio, results in a relatively fragile structure that requires careful handling to prevent breakage from localized stresses. Due to the relatively small size of the elongate solar cells (compared to the size of a semiconductor wafer) a large number of elongate solar cells is required for the manufacture of even a modest-sized solar collecting panel. In view of this, a relatively large number of elongate solar cells must be carefully removed from a wafer and positioned on a substrate for the fabrication of a solar collecting panel.

The elongate solar cells may be bifacial, having solar collecting surfaces on both of their opposing major faces, and may be visually symmetrical. However, the elongate solar cells are not electrically symmetrical (i.e., each elongate solar cell has a polarity) and proper orientation and electrical connection of each elongate solar cell to other elongate solar cells of the assembly is important. This requirement creates difficulties in manufacturing, since the polarity of each elongate solar cell may not be determined visually, and each elongate solar cell must be oriented properly in an assembly for the desired application.

In view of the significance of the proper orientation and placement of each elongate solar cell into an assembly, the fragile nature of the elongate solar cells, and the conventional techniques of handling elongate solar cells one at a time when fabricating solar collecting panels, the manufacturing of assemblies utilizing elongate solar cells has been relatively time consuming and expensive, rendering the commercial production of solar collecting panels using the elongate solar cells only marginally economically feasible, if at all.

In view of the foregoing, improved devices and assemblies including elongate solar cells and improved methods of manufacturing assemblies utilizing elongate solar cells would be desirable.

### BRIEF DESCRIPTION OF THE DRAWINGS

FIG. 1 shows an isometric view of a semiconductor wafer for utilization in making elongate solar cells for assemblies according to embodiments of the present invention.

FIG. 2 shows an isometric view of the semiconductor wafer of FIG. 1 including elongate solar cell precursor structures.

FIG. 3A shows a perspective view of an elongate solar cell formed from the elongate solar cell precursor structures of FIG. 2.

FIG. 3B shows a cross-sectional view of the elongate solar cell of FIG. 3A.

FIG. 4 shows an isometric view of a transfer structure attached to the elongate solar cell precursor structures of the semiconductor wafer of FIG. 2 according to an embodiment of the present invention.

FIG. 5 shows an isometric view of the elongate solar cell precursor structures of FIG. 4 singulated from the wafer to form elongate solar cells attached to the transfer structure according to an embodiment of the present invention.

FIG. 6 shows a side view of the elongate solar cells attached to the transfer structure of FIG. 5, the elongate solar cells further attached to an expandable fixture according to an embodiment of the present invention.

FIG. 7 shows a side view of the elongate solar cells on the expandable fixture of FIG. 6, wherein the expandable fixture is in an expanded position and a substrate is positioned over and attached to the elongate solar cells according to an embodiment of the present invention.

FIG. 8 shows a side view of the elongate solar cells attached to the transfer structure of FIG. 5, the elongate solar cells further attached to a corrugated substrate of another expandable fixture according to an embodiment of the present invention.

FIG. 9 shows a side view of a substrate attached to the expandable fixture of FIG. 8 in an expanded position, prior to the substrate becoming corrugated according to an embodiment of the present invention.

FIG. 10 shows a side view of the substrate of FIGS. 8 and 9 in a flattened configuration having the elongate solar cells attached thereto and a substrate positioned over and attached to the elongate solar cells according to an embodiment of the present invention.

FIG. 11 shows a side view of the elongate solar cells attached to the transfer structure of FIG. 5, the elongate solar cells further attached to a deformable substrate of yet another expandable fixture according to an embodiment of the present invention.

FIG. 12 shows a side view of the deformable substrate of FIG. 11 in a stretched and plastically deformed state having the elongate solar cells attached thereto and a substrate positioned over and attached to the elongate solar cells according to an embodiment of the present invention.

FIG. 13 shows a side view of solar panel assembly having a plurality of elongate solar cells positioned on a substrate, major surfaces of the plurality of elongate solar cells oriented in a non-planar configuration according to an embodiment of the present invention.

FIG. 14 shows a side view of solar panel assembly having a plurality of elongate solar cells in a corrugated arrangement according to an embodiment of the present invention.

FIG. 15 shows a side view of a solar panel assembly having a plurality of elongate solar cells arranged on a three-dimensionally shaped surface of a substrate according to an embodiment of the present invention.

FIG. 16 shows an isometric view of an elongate solar cell exhibiting a spiral shape according to an embodiment of the present invention.

### DETAILED DESCRIPTION

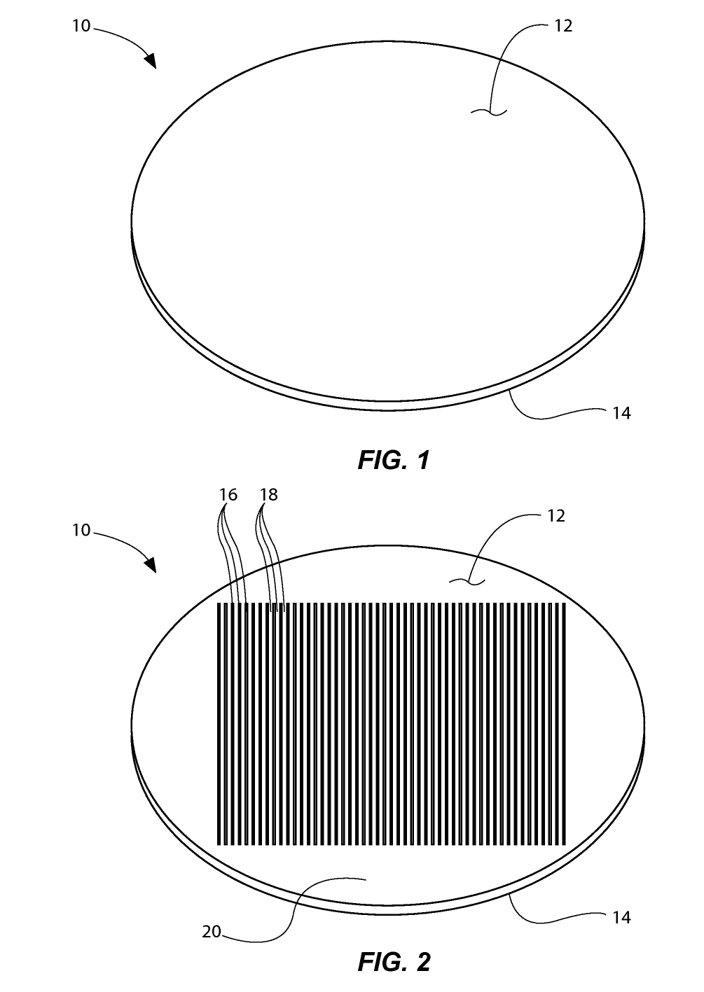

A semiconductor wafer 10, such as a silicon wafer as shown in FIG. 1, may include a first major surface 12 and an opposing second major surface 14. The semiconductor wafer 10 may be a p-type semiconductor wafer such that at least a central region of the semiconductor wafer 10, between the first major surface 12 and the second major surface 14, may be doped with a p-type dopant. The semiconductor material near the first major surface 12 of the semiconductor wafer 10 may be relatively heavily doped with a p-type dopant, such as by a surface diffusion of one or more p-type dopants at the first major surface 12 of the semiconductor wafer 10. Additionally, the semiconductor material near the second major surface 14 of the semiconductor wafer 10 may be relatively heavily doped with an n-type dopant, such as by a surface diffusion of one or more n-type dopants at the second major surface 14 of the semiconductor wafer 10. While the present disclosure describes embodiments utilizing conventional, substantially circular, semiconductor wafers, the invention is not so limited and other bulk semiconductor substrates from which slivers comprising elongate solar cells may be fabricated may also be employed. Therefore, the term “wafer” as employed herein means and includes bulk semiconductor substrates in general.

As shown in FIG. 2, a plurality of elongated slots 16 may be formed in the semiconductor wafer 10, to define therebetween a plurality of elongate solar cell precursor structures 18 therebetween. For example, the slots 16 may be formed by one or more of sawing, such as by a diamond-edged dicing saw having a narrow blade, laser ablation, water-jet cutting, etching, such as by a wet anisotropic etch using potassium hydroxide solution (KOH), and other techniques recognized by one of ordinary skill in the art. Optionally, elongated slots 16 may be cut in various regions of the wafer 10 and in different directions to maximize usage of the semiconductor material of the wafer 10, and the wafer 10 may be further cut to form a plurality of wafer frames (not shown) from uncut portions of the wafer 10 surrounding each group of elongate solar cell precursor structures 18. After the slots 16 have been formed, the ends of each of the elongate solar cell precursor structures 18 may remain attached to a wafer frame 20. Optionally, after the slots 16 have been formed, a surface treatment may be applied to the major surfaces of the elongate solar cell precursor structures 18. For example, a roughening treatment may be applied to the major surfaces of the elongate solar cell precursor structures 18. Additionally, a conductive material layer, such as a conductive metal layer, may be provided on the upper and lower edges of each of the elongate solar cell precursor structures 18.

The elongate solar cell precursor structures 18 are elongated structures with a length that is typically much greater than its height and width and having ends attached to the wafer frame 20, each of the elongate solar cell precursor structures 18 and the wafer frame 20 being a unitary structure. Once the ends of an elongate solar cell precursor structure 18 have been singulated from the wafer frame 20 an elongate solar cell is formed.

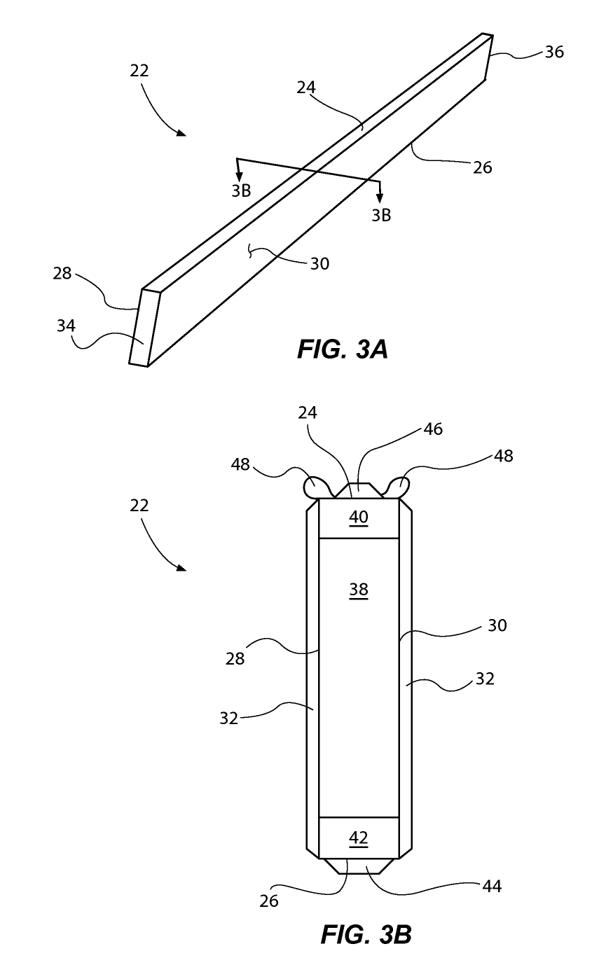

A resulting elongate solar cell 22, as shown in FIGS. 3A and 3B, may have a first edge 24 (e.g., a first elongate edge) and an opposing, second edge 26 (e.g., a second elongate edge). The first edge 24 may be formed from the first major surface 12 of the semiconductor wafer 10 as a result of forming the slots 16 into the semiconductor wafer 10. Similarly, the second edge 24 may be formed from the opposing second major surface 14 of the semiconductor wafer 10 by formation of slots 16. The elongate solar cell 22 may also have a first major face 28 and an opposing second major face 30, which may be formed from the interior material of the semiconductor wafer 10 after the slots 16 are formed into the semiconductor wafer 10. Optionally, as shown in FIG. 3B, a material, such as an oxide 32, may coat the first and second major surfaces. Each of the first and second major faces 28 and 30 of the elongate solar cells 22 may be configured as solar collecting surfaces and each of the elongate solar cells 22 may, as desired, be configured as bi-facial solar cell. The elongate solar cells 22 may also have a first end 34 and an opposing second end 36 (shown in FIG. 3A). A length of the first and second ends 34 and 36 defines a height of each of the elongate solar cells 22 and corresponds to a distance between the first edge 24 and the second edge 26. However, other sizes and shapes of the elongate solar cell structure are contemplated herein.

Each elongate solar cell 22 may be a solid state device that converts the energy of sunlight or other light or energy sources into electricity by the photovoltaic effect. As seen in FIG. 3B, each elongate solar cell 22 has an interior body 38 formed of the semiconductor material of the semiconductor wafer that is made of a lightly p-type doped material. Each elongate solar cell 22 further includes a relatively heavily p-type doped material region 40 near the first edge 24 and a relatively heavily n-type doped material region 42 near the second edge 26. Optionally, each elongate solar cell 22 may include a thin oxide 32 on one or both of the first and second primary surfaces 28 and 30. A conductive material such as a metal 44 may be included along the second edge 26 to provide an electrical path to the n-doped material region 42 to the elongate solar cell 22. Similarly, a conductive material such as a metal 46 may be included along the first edge 24 to provide an electrical path to the p-type doped material region 40 of the elongate solar cell 22. In one embodiment, a dielectric material 48 may additionally be applied along one or more edges of the elongate solar cell 22. The dielectric material 48 may be configured to increase the efficiency of the elongate solar cell 22.

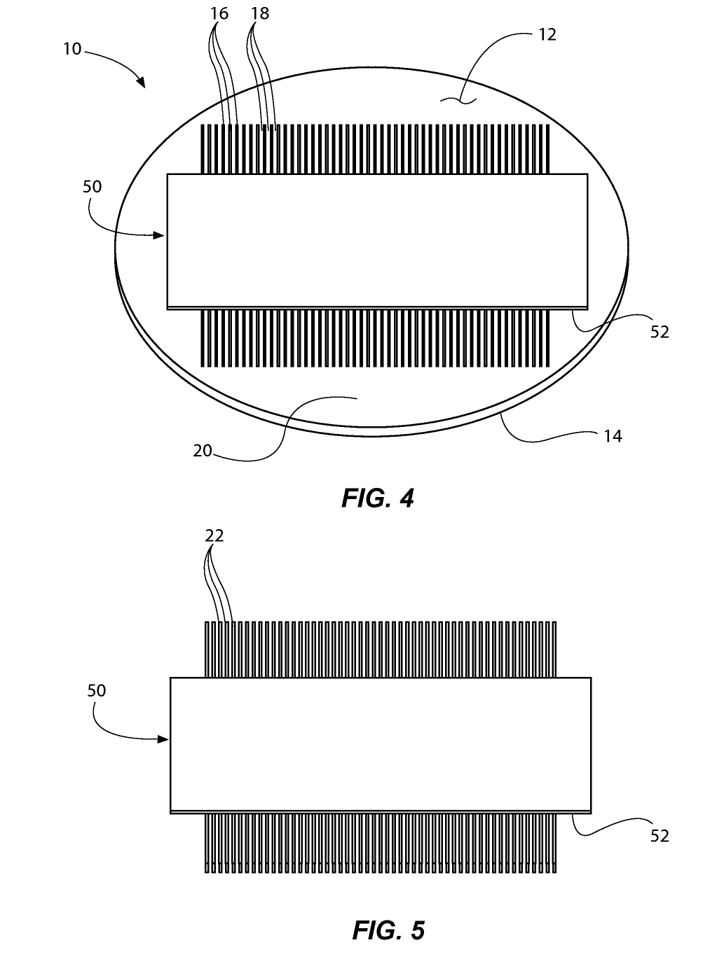

As shown in FIG. 4, after the elongate solar cell precursor structures 18 have been defined (as shown in FIG. 2), a transfer structure 50 having an adhesive surface 52 may be positioned over and adhered to one of the first edge 24 and the second edge 26 of each of the plurality of elongate solar cell precursor structures 18, or at least a group of elongate solar cell precursor structures 18 of the plurality of elongate solar cell precursor structures 18. For example, the adhesive surface 52 may be adhered to the first edge 24 of each of the plurality of elongate solar cell precursor structures 18. In some embodiments, the adhesive surface 52 may comprise a wax plate (free-standing or supported by a substrate for enhanced mechanical strength during handling) that may be relatively soft at the temperature at which it is applied to the first edges 24 of the elongate solar cell precursor structures 18, surrounding a portion of the first edge 24 of each elongate solar cell precursor structure 18 and adhering thereto. Optionally, the wax plate may be heated or otherwise softened prior to contacting and adhering to the elongate solar cell precursor structures 18. In additional embodiments, an adhesive layer 52 that is softenable by heat, light, or another energy source may be utilized, and softened prior to contact with and adhesion to the elongate solar cell precursor structures 18. If the adhesive layer 52 is heated, it may be heated to a temperature below 400° C. to prevent thermal damage to the elongate solar cell precursor structures 18. Utilizing an adhesive layer 52 that is relatively soft and pliable during attachment allows the adhesive layer 52 to conform to and extend around a portion of the edge 24, 26 of the elongate solar cell precursor structures 18, which may provide excellent support and adhesion to the elongate solar cell precursor structures 18, and may prevent rotational, angular displacement of the elongate solar cells 22 relative to one another and mutual contact of the elongate solar cells 22 after they have been singulated from the wafer frame 20. In some embodiments, after the adhesive layer 52 has been positioned on the first edges 24 of the elongate solar cell precursor structures 18, the adhesive layer 52 may be treated so as to become stiffer; for example a wax plate may be cooled, prior to singulation of the elongate solar cells 22. In further embodiments, the adhesive layer 52 may remain relatively soft and pliable. As used herein, the terms “adhesive,” “adhering,” “adhere” and the like are to be interpreted in a broad and non-limiting sense, indicating only that a structure provides a bonding or other attachment function by which an elongate solar cell precursor structure or elongate solar cell may be held temporarily or permanently in a desired position. Similarly, any reference to attaching one structure to another herein is to be interpreted in a broad and non-limiting sense and encompasses a wide variety of attachment compositions, structures and mechanisms.

After the adhesive surface 52 of the transfer structure 50 has been attached to the elongate solar cell precursor structures 18, the elongate solar cell precursor structures 18 may be cut or otherwise singulated from the wafer frame 20 to provide a plurality of individual elongate solar cells 22 attached to the transfer structure 50, as shown in FIG. 5. In some embodiments, the transfer structure 50 may be attached to a central region of the elongate solar cell precursor structures 18 and the ends of the elongate solar cell precursor structures 18, where each elongate solar cell structure 18 attaches to the wafer frame 20, may be left open and accessible. The ends of the elongate solar cell precursor structures 18 may then be separated from the wafer frame 20, such as by one or more of sawing, such as by a dicing saw, laser ablation, water-jet cutting, and other techniques known to one of ordinary skill in the art. After the elongate solar cell precursor structures 18 have been cut to form a plurality of individual elongate solar cells 22, the plurality of individual elongate solar cells 22 may be simultaneously moved together as a unit by the transfer structure 50 for further processing, and the elongate solar cells 22 positions relative to one another may be maintained by the transfer structure 50.

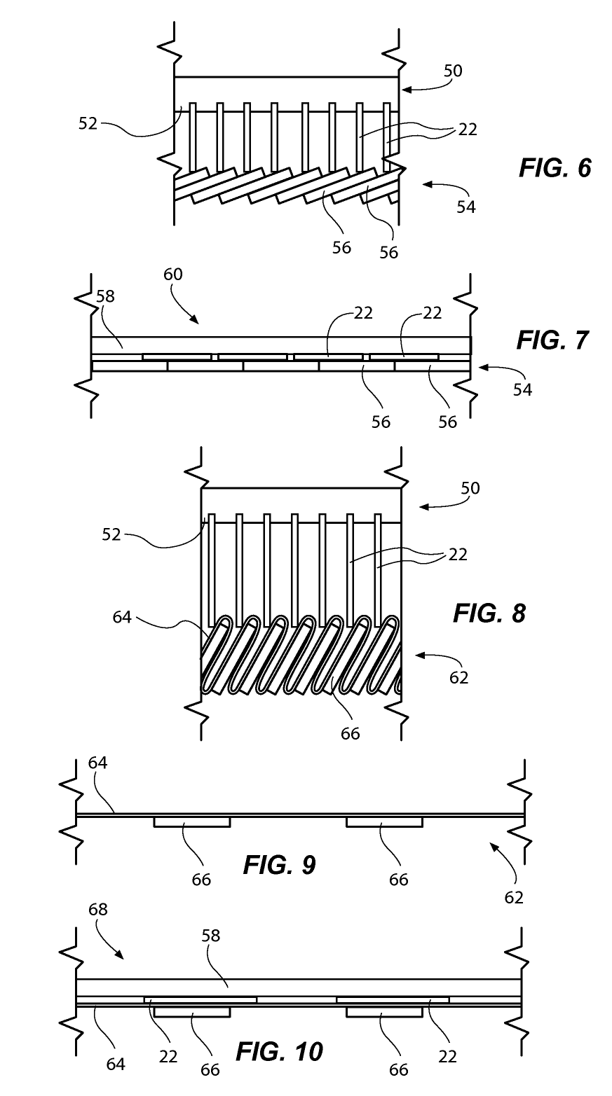

The transfer structure 50 may then be manipulated to simultaneously move and position the individual elongate solar cells 22 onto an expandable fixture for individual positioning of the elongate solar cells 22 for installation into an assembly. In one embodiment, such as shown in FIG. 6, the expandable fixture 54 may include a plurality of fingers 56, each finger 56 corresponding and positioned with respect to an elongate solar cell 22 attached to the transfer structure 50. Each finger 56 may include a feature for the attachment of an elongate solar cell 22. For example, each finger 56 may have a geometric feature, such as a pocket, for receiving an edge 24, 26 of an elongate solar cell 22. For example, a slot sized to receive an edge 24, 26 of an elongate solar cell 22 may be formed in a surface of each finger 56. In an additional example, each finger 56 may include an adhesive for bonding to an edge 24, 26 of an elongate solar cell 22. In a further example, each finger 56 may include one or more apertures in a face thereof in fluid communication with a vacuum source for forming a vacuum between each finger 56 and edge 24, 26 of an elongate solar cell 22.

Upon attaching the elongate solar cells to the fingers 56 of the expandable fixture 54, the transfer structure 50 may be removed. To facilitate removal of the transfer structure 50, a treatment may be applied to the adhesive surface 52. For example, the adhesive surface may be softened, melted, or otherwise weakened, such as by the application of heat, light, and/or chemicals. In some embodiments, the adhesive surface 52 (e.g., wax plate) may be broken down to facilitate removal of the transfer structure 50, such as by the application of heat and/or chemicals. For example, the adhesive surface 52 may be broken down by one or more of vaporization, liquefaction, volatilization, and dissolution.

After the transfer structure 50 has been removed, the expandable fixture 54 may be expanded by lateral movement of the fingers 56 away from one another in a direction transverse to the longitudinal axes of the fingers 56. During expansion of the expandable fixture 54, the plurality of fingers 56 of the expandable fixture 54 may become spaced apart and consequently orient the elongate solar cells 22 to a desired configuration.

Upon expansion of the expandable fixture 54, such as shown in FIG. 7, each of the elongate solar cells 22 may be moved and spaced relative to adjacent elongate solar cells 22 on the expandable fixture 54 and each of the elongate solar cells 22 may be positioned in a desired orientation for assembling into a subassembly.

After the elongate solar cells 22 have been positioned in a desired orientation by the expandable fixture 54, such as shown in FIG. 7, a substrate 58 (e.g., a transparent substrate) may be applied over and adhered to the plurality of elongate solar cells 22 to form an assembly 60. Upon adherence to the substrate 58, the elongate solar cells 22 may be electrically coupled (i.e., wired) together in the assembly 60, such as for a solar collecting panel for a solar array.

In some embodiments, the substrate 58 may include electrically conductive traces formed thereon or applied thereto (i.e., the substrate may be pre-wired). The electrically conductive traces may be aligned with the elongate solar cells 22 and electrically coupled to the conductive material 44, 46 on the first and second edges 24 and 26 of each of the elongate solar cells 22. In additional embodiments, electrically conductive traces may be provided on the substrate 58 and coupled to the elongate solar cells 22 after the elongate solar cells 22 have been adhered to the substrate 58.

In additional embodiments, such as shown in FIG. 8, a transfer structure 62 may include a corrugated substrate 64 having regions positioned for receiving the elongate solar cells 22. Each of the elongate solar cells 22 may be positioned respectively onto corresponding regions of the corrugated substrate 64 and may be attached to thereto, such as by an adhesive. In some embodiments, the corrugated substrate 64 may be permanently attached to fingers 66 of the transfer structure 62 and may be reusable. In additional embodiments, the corrugated substrate 64 may be temporarily attached to the fingers 66 of the expandable fixture 62. For example, the corrugated substrate 64 may be a substrate that is incorporated into an assembly and the elongate solar cells 22 may be permanently attached to the substrate 64.

In one embodiment, as shown in FIG. 9, a relatively flexible and substantially flat substrate 64 may be adhered to the fingers 66 when the expandable fixture 62 is in an expanded position, such as shown in FIG. 9. The expandable fixture 62 may then be contracted and the fingers 66 may cause the previously flat substrate 64 to form a corrugated substrate 64, as shown in FIG. 8.

Upon attaching the elongate solar cells 22 onto the corrugated substrate 64 of the expandable fixture 62, as shown in FIG. 8, the transfer structure 50 may be removed. To facilitate removal of the transfer structure 50, a treatment may be applied to the adhesive surface 52. For example, the adhesive surface may be softened, melted, or otherwise weakened, such as by the application of heat, light, and/or chemicals. In some embodiments, the adhesive surface 52 (e.g., wax plate) may be broken down to facilitate removal of the transfer structure 50, such as by the application of heat and/or chemicals. For example, the adhesive surface 52 may be broken down by one or more of vaporization, liquefaction, volatilization, and dissolution.

After the transfer structure 50 has been removed, the expandable fixture 62 may be expanded. During expansion of the expandable fixture 62, the corrugated substrate 64 (FIG. 8) may be expanded and the corrugations may be flattened (FIG. 9) to provide the desired orientation of the elongate solar cells 22. Upon expanding of the expandable fixture 62 and flattening of the substrate 64, as shown in FIG. 10, each of the elongate solar cells 22 may be moved and spaced relative to adjacent elongate solar cells 22 on the expandable fixture 62 and each of the elongate solar cells 22 may be positioned in a desired orientation for assembling into an assembly. Substrate 64 may be formed of an elastically or plastically deformable material, to provide a capability for spacing elongate solar cells laterally apart by an adjustable distance.

After the elongate solar cells 22 have been positioned in a desired orientation by the expandable fixture 62, such as shown in FIG. 10, a substrate 58 (e.g., a transparent substrate) may be applied over and adhered to the plurality of elongate solar cells 22 to an assembly 68. Upon adherence to the substrate 58, the elongate solar cells 22 may be electrically coupled (i.e., wired) together in the assembly 68, such as for a solar collecting panel for a solar array.

In some embodiments, the substrate 58 may include electrically conductive traces formed thereon or applied thereto (i.e., the substrate may be pre-wired). The electrically conductive traces may be aligned with the elongate solar cells 22 and electrically coupled to the conductive material 44, 46 on the first and second edges 24 and 26 of the elongate solar cells 22. In additional embodiments, electrically conductive traces may be provided on the substrate 58 and coupled to the elongate solar cells 22 after the elongate solar cells 22 have been adhered to the substrate 58.

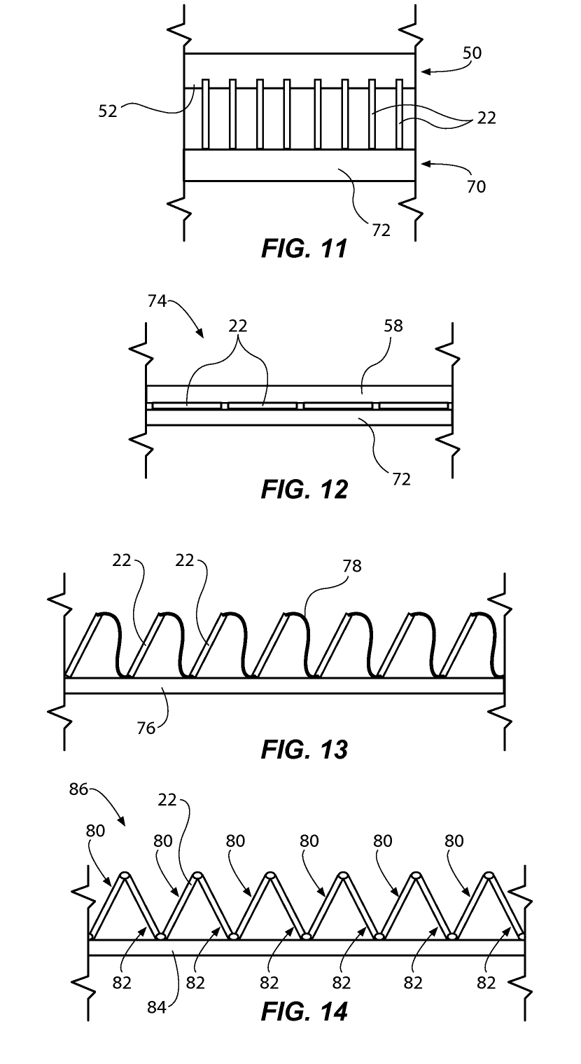

In further embodiments, such as shown in FIG. 11, an expandable fixture 70 may include a deformable substrate 72 that is capable of substantial stretching without rupturing.

Upon attaching the elongate solar cells 22 onto the deformable substrate 72 of the expandable fixture 70, the transfer structure 50 may be removed. To facilitate removal of the transfer structure 50, a treatment may be applied to the adhesive surface 52. For example, the adhesive surface may be softened, melted, or otherwise weakened, such as by the application of heat, light, and/or chemicals. In some embodiments, the adhesive surface 52 (e.g., wax plate) may be broken down to facilitate removal of the transfer structure 50, such as by the application of heat and/or chemicals. For example, the adhesive surface 52 may be broken down by one or more of vaporization, liquefaction, volatilization, and dissolution.

After the transfer structure 50 has been removed, the expandable fixture 70 may be expanded. During the expansion of the expandable fixture 70, the deformable substrate 72 may be deformed, such as by stretching, to provide the desired orientation and spacing of the elongate solar cells 22 positioned thereon, and secured at its edges to a frame to maintain shape. After the deformable substrate 72 has been deformed, and optionally during deformation, a treatment may be applied to relieve any elastic deformation of the deformable substrate 72, such that the deformable substrate 72 may be plastically deformed (i.e., permanently deformed). For example, a deformable substrate 72 may comprise a polymer material and may be exposed to a heat treatment to facilitate plastic deformation of the deformable substrate 72.

Upon expansion of the expandable fixture 70 and the plastic deformation of the deformable substrate 72, such as shown in FIG. 12, each of the elongate solar cells 22 may be moved and spaced relative to adjacent elongate solar cells 22 on the expandable fixture 70 and each of the elongate solar cells 22 may be positioned in a desired orientation and spacing for assembling into an assembly.

After the elongate solar cells 22 have been positioned in a desired orientation by the expandable fixture 70, such as shown in FIG. 12, a substrate 58 (e.g., a transparent substrate) may be applied over and adhered to the plurality of elongate solar cells 22 to foam an assembly 74. Upon adherence to the substrate 58, the elongate solar cells 22 may be electrically coupled (i.e., wired) together in the assembly 74, such as for a solar collecting panel for a solar array.

In some embodiments, the substrate 58 may include electrically conductive traces formed thereon or applied thereto, as by screen-printing (i.e., the substrate may be pre-wired). The electrically conductive traces may be aligned with the elongate solar cells 22 and electrically coupled to the conductive material 44, 46 on the first and second edges 24 and 26 of the elongate solar cells 22. In additional embodiments, electrically conductive traces may be provided on the substrate 58 and coupled to the elongate solar cells 22 after the elongate solar cells 22 have been adhered to the substrate 58.

In some embodiments, the plurality of elongate solar cells 22 may oriented by an expandable fixture 54, 62, 70 to each be positioned at a non-parallel angle to a major plane of the assembly into which they are incorporated. Specifically, the plurality of elongate solar cells 22 may be coupled to a substrate 76 and oriented such that the primary surfaces 28, 30 of the plurality of elongate solar cells 22 may be positioned at an acute, included angle relative to the substrate 76, as shown in FIG. 13. In such embodiments, a plurality of elongate solar cells 22 may be attached to a transfer structure 50 and transferred to an expandable fixture 54, 62, 70. Each of the elongate solar cells may have an end coupled to the expandable fixture 54, 62, 70 and the expandable fixture 54, 62, 70 may be expanded, spacing each of the elongate solar cells 22 apart. A substrate may then be adhered to an edge 24, 26 of each of the elongate solar cells 22 and the elongate solar cells 22 may be electrically connected together. In some embodiments, conductors in the form of wiring 78 may be provided as a wire mesh extending along the ends 34, 36 of the elongate solar cells, coupling the elongate solar cells in series, a first edge 24 of an elongate solar cell 22 coupled to a second edge 26 of an adjacent elongate solar cell 22, and so on. By locating the wiring 78 at the ends 34, 36 of the elongate solar cells 22, the wiring may not cast any significant shadows on the primary surfaces 28, 30 (i.e., the solar collecting surfaces) of the elongate solar cells 22. Further, in an embodiment as depicted in FIG. 13, each major face 28, 30 of each elongate solar cell 22 may be exposed to solar radiation, either directly or by reflection from another major face 28, 30 of an adjacent elongate solar cell 22.

In another embodiment, a plurality of elongate solar cells 22 may be oriented to provide a corrugated solar collecting surface, as shown in FIG. 14. To manufacture such an embodiment, a first plurality 80 of elongate solar cells 22 may have their first edges 24 attached to a transfer structure 50, such as shown in FIG. 5. Then, the first plurality 80 of elongate solar cells 22 may each be positioned adjacent an elongate solar cell precursor structure 18 of a plurality of elongate solar cell precursor structures 18 having an opposite orientation attached to a wafer frame 20, such that the first plurality 80 of elongate solar cells 22 may intermesh with the plurality of elongate solar cell precursor structures 18 having an opposite polarity. The plurality of elongate solar cell precursor structures 18 may then be attached to the same transfer structure 50 (not shown in FIG. 14) and singulated from the wafer frame 20 to provide a second plurality 82 of elongate solar cells 22 having their second edges 26 attached to the transfer structure 50. In view of this, the elongate solar cells 22 attached to the transfer structure 50 may alternate as to their polarity and which edge is attached to the transfer structure 50. The elongate solar cells 22 may then be positioned onto an expandable fixture and removed from the transfer structure 50. The expandable fixture may then be used to position the first plurality 80 of elongate solar cells 22 and the second plurality 82 of elongate solar cells 22 into a corrugated orientation and position and the elongate solar cells 22 may be adhered to a substrate 84 and electrically connected to form an assembly 86. Again, in an embodiment as depicted in FIG. 14, each major face 28, 30 of each elongate solar cell 22 may be exposed to solar radiation, either directly or by reflection from another major face 28, 30 of an adjacent elongate solar cell 22.

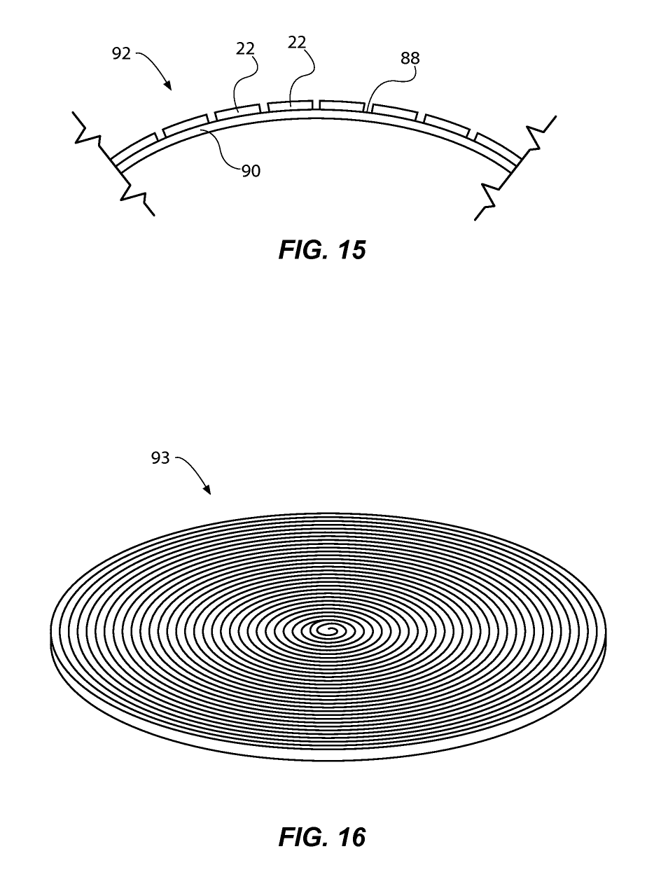

Such assembly methods and devices for elongate solar cell handling and subassembly construction as described herein may enable the handling of extremely delicate elongate solar cells that are thinner than could be handled with conventional handling methods and devices. Additionally, elongate solar cells 22 may be positioned and adhered to non-planar surfaces. For example, an expandable fixture may position a plurality of elongate solar cells 22 in an arcuate arrangement, such as shown in FIG. 15, or some other three-dimensional arrangement, and a corresponding surface 88 of a substrate 90 may be positioned over and adhered to the plurality of elongate solar cells 22 to form an assembly 92. Further, when an expandable fixture comprising a plurality of fingers is employed, the plurality of fingers may be expanded on one end only, or to a greater degree on one end than on an opposing end, to form a fan-shaped array of elongate solar cells. Similarly, a deformable substrate may be non-linearly deformed so that one edge thereof is stretched to a greater degree than an opposing edge to form a fan-shaped elongate solar cell array. In both such instances, the expandable fixture may also be expanded, for example, convexly or concavely. Such a shape may be useful, for example, for application of assemblies of vertically oriented elongate solar cells to curved surfaces, such as surfaces of light fixture poles or power poles.

As the elongate solar cells may be especially thin, for example on the order of about 15 microns to about 400 microns in thickness, they may also be especially flexible, allowing an elongate solar cell to have its shape changed after being cut from a wafer. In view of this, elongate solar cells 93 having a non-linear shape may be cut from a wafer. For example, elongate solar cells or solar cell precursor structures may be severed from a wafer in concentric arcuate shapes, a continuous, elongated spiral shape, such as shown in FIG. 16, or another nonlinear shape, such that the elongate solar cells or solar cell precursor structures exhibit a curved shape when in an as-formed state. After formation, a thin, non-linear, elongate solar cell may be linearized for incorporation in an array of elongate solar cells. Use of a non-linear shape may enable more of a semiconductor wafer to be utilized in making elongate solar cells and may allow longer elongate solar cells to be cut from a wafer, when compared to elongate solar cells formed by linear cuts. The latter advantage may enable fabrication of solar collection panels comprising far fewer elongate solar cells and, thus, requiring fewer electrical connections with consequent lower cost and higher reliability.

### CONCLUSION

In one embodiment, a method of assembling elongate solar cells may comprise forming a unitary structure comprising a plurality of elongate solar cell precursor structures from a semiconductor wafer and attaching an edge of each of the plurality of elongate solar cell precursor structures to an adhesive surface of a transfer structure. The method may further comprise attaching the plurality of elongate solar cells to an expandable fixture by contacting a portion of the expandable fixture at least with an opposing edge of each elongate solar cell precursor structure of the plurality and expanding the expandable fixture to change at least one of an orientation and a position of elongate solar cells of the plurality relative to one another.

In a further embodiment, solar panel assembly may comprise a plurality of elongate solar cells positioned on a substrate, major faces of the plurality of elongate solar cells oriented in a non-planar configuration.

In another embodiment, a solar panel assembly may comprise a plurality of elongate solar cells attached to a plastically deformed substrate.

In yet another embodiment, a solar panel assembly may comprise a plurality of elongate solar cells arranged on a three-dimensionally shaped surface of a substrate.

In a further embodiment, an elongate solar cell may comprise a non-linear shape in an as-formed state.

In yet a further embodiment, a solar panel assembly may comprise a plurality of elongate solar cells in a corrugated arrangement to provide a corrugated solar collecting surface.

In a still further embodiment, transfer structures and expandable fixtures useful for performing methods of the present disclosure are described.

While the invention is susceptible to various modifications and alternative forms, specific embodiments have been shown by way of example in the drawings and have been described in detail herein. However, the invention is not intended to be limited to the particular forms disclosed. Rather, the invention is to cover all modifications, equivalents, and alternatives falling within the scope of the invention as defined by the following appended claims and their legal equivalents.

What is claimed is:

1. A method of assembling elongate solar cells, the method comprising:
forming a unitary structure comprising a plurality of elongate solar cell precursor structures from a semiconductor wafer;
attaching an edge of each of the plurality of elongate solar cell precursor structures to an adhesive surface of a transfer structure;
singulating the plurality of elongate solar cell precursor structures from the unitary structure to form a plurality of elongate solar cells attached to the transfer structure;
attaching the plurality of elongate solar cells to an expandable fixture by contacting a portion of the expandable fixture at least with an opposing edge of each elongate solar cell precursor structure of the plurality; and
expanding the expandable fixture to change at least one of an orientation and a position of the elongate solar cells of the plurality of elongate solar cells relative to one another.

2. The method of claim 1, wherein attaching each of the plurality of elongate solar cell precursor structures to the adhesive surface of the transfer structure comprises attaching a wax plate of the transfer structure to the edge of each elongate solar cell precursor structure of the plurality of elongate solar cell precursor structures.

3. The method of claim 1, further comprising modifying at least the adhesive surface of the transfer structure to attach the edge of each elongate solar cell precursor structure of the plurality of elongate solar cell precursor structures to the adhesive surface of the transfer structure.

4. The method of claim 3, wherein modifying at least the adhesive surface comprises at least one of exposing the adhesive surface to heat and exposing the adhesive surface to light.

5. The method of claim 3, further comprising reforming the at least modified adhesive surface after attaching the plurality of elongate solar cell precursor structures to the transfer structure.

6. The method of claim 1, further comprising detaching the transfer structure from the plurality of elongate solar cells prior to expanding the expandable fixture.

7. The method of claim 6, further comprising breaking down at least the adhesive surface of the transfer structure by one or more of vaporization, liquefaction, volatilization, and dissolution to facilitate detaching the transfer structure from the plurality of elongate solar cells.

8. The method of claim 1, wherein attaching the plurality of elongate solar cells to the expandable fixture further comprises attaching each of the plurality of elongate solar cells to a corresponding finger of a plurality of fingers of the expandable fixture and wherein expanding the expandable fixture further comprises moving the plurality of fingers with respect to one another.

9. The method of claim 1, wherein attaching the plurality of elongate solar cells to the expandable fixture further comprises attaching each of the plurality of elongate solar cells to a corrugated substrate and wherein expanding the expandable fixture further comprises stretching the corrugated substrate and flattening the corrugations of the corrugated substrate to provide a relatively flat substrate.

10. The method of claim 9, wherein attaching each of the plurality of elongate solar cells to the corrugated substrate comprises permanently attaching each of the plurality of elongate solar cells to the corrugated substrate and including the corrugated substrate in an assembly incorporating the plurality of elongate solar cells.

11. The method of claim 1, wherein attaching the plurality of elongate solar cells to the expandable fixture further comprises attaching each of the plurality of elongate solar cells to a deformable substrate and wherein expanding the expandable fixture further comprises stretching the deformable substrate and plastically deforming the deformable substrate.

12. The method of claim 11, further comprising applying a treatment to the deformable substrate upon stretching the deformable substrate to plastically deform the deformable substrate.

13. The method of claim 12, wherein applying the treatment comprises applying heat.

14. The method of claim 1, further comprising adhering a substrate to the plurality of elongated solar cells after expanding the expandable fixture to change at least one of an orientation and a position of elongate solar cells of the plurality of elongate solar cells relative to one another.

15. The method of claim 14, further comprising orienting the plurality of elongate solar cells such that a major face of each of the plurality of elongate solar cells is positioned at a non-parallel angle relative to the substrate.

16. The method of claim 15, further comprising locating electrical conductors at the ends of the plurality of elongate solar cells and electrically coupling the plurality of elongate solar cells to the electrical conductors.

17. The method of claim 14, further comprising electrically coupling each of the plurality of elongated solar cells to conductive traces preformed on the substrate.

18. The method of claim 14, further comprising electrically coupling the plurality of elongated solar cells together by providing conductive paths therebetween after adhering the substrate to the plurality of elongated solar cells.

19. The method of claim 1, further comprising:
attaching the adhesive surface of the transfer structure to another edge of each of another plurality of elongate solar cell precursor structures with each elongate solar cell precursor structure of the another plurality of elongate solar cell precursor structures adjacent to at least one elongate solar cell of the plurality of elongate solar cells with a polarity of the elongate solar cell precursor structures opposing a polarity of the elongate solar cells; and
singulating the another plurality of elongate solar cell precursor structures to form another plurality of elongate solar cells attached to the transfer structure to provide a combined plurality of elongate solar cells having alternating polarity attached to the adhesive surface of the transfer structure.

20. A solar panel assembly, comprising a plurality of elongate solar cells positioned on a substrate with major faces of the plurality of elongate solar cells oriented in a non-planar configuration.

21. The solar panel assembly of claim 20, wherein each of the plurality of elongate solar cells is oriented such that a major face of each of the plurality of elongate solar cells is positioned at a non-parallel angle relative to the substrate.

22. A solar panel assembly, comprising a plurality of elongate solar cells attached to a plastically deformed substrate.

23. A solar panel assembly, comprising a plurality of elongate solar cells arranged on a three-dimensionally shaped surface of a substrate.

24. An elongate solar cell, configured in a non-linear shape in an as-formed state.

25. The elongate solar cell of claim 25, wherein the non-linear shape comprises one of a circular shape and a spiral shape.

26. A solar panel assembly, comprising a plurality of elongate solar cells mutually joined proximate edges thereof in a corrugated arrangement.

27. The solar panel assembly of claim 26, wherein adjacent elongate solar cells of the plurality are oriented with alternating polarities.
